(19) United States
(12) Patent Application Publication
(10) Pub. No.: US 2022/0091697 A1
(43) Pub. Date: Mar. 24, 2022

(54) Input Apparatus

(71) Applicant: Alps Alpine Co., Ltd., Tokyo (JP)

(72) Inventor: Hayato Miyagawa, Miyagi-ken (JP)

(21) Appl. No.: 17/540,705

(22) Filed: Dec. 2, 2021

Related U.S. Application Data
(63) Continuation of application No. PCT/JP2020/011456, filed on Mar. 16, 2020.

(30) Foreign Application Priority Data
Jun. 28, 2019 (JP) 2019-122076

(51) Int. Cl. G06F 3/044; G06F 3/041; G06F 3/0362; H03K 17/96

(52) U.S. Cl. CPC G06F 3/0446; G06F 3/0412; H03K 17/962; G06F 3/0362; G06F 3/0416

(57) ABSTRACT

An input apparatus includes a casing having an operation surface, an opposite surface, a side surface, and an inner space, a substrate disposed along the opposite surface in the inner space, a top-surface-operation detecting unit including a first electrode pattern on the upper surface of the substrate, the top-surface-operation detecting unit detecting a change in electrostatic capacitance of the first electrode pattern caused by capacitive coupling to an operating body that comes close to or into contact with the operation surface, a side-surface-operation detecting unit on the side surface of the substrate, below the top-surface-operation detecting unit, the side-surface-operation detecting unit detecting a change in electrostatic capacitance caused according to a side surface operation performed on the side surface of the casing by the operating body, and a control unit that outputs an operation signal based on detection results of the top-surface-operation detecting unit and the side-surface-operation detecting unit.

### CLAIM OF PRIORITY

This application is a Continuation of International Application No. PCT/JP2020/011456 filed on Mar. 16, 2020, which claims benefit of Japanese Patent Application No. 2019-122076 filed on Jun. 28, 2019. The entire contents of each application noted above are hereby incorporated by reference.

### BACKGROUND OF THE INVENTION

### 1. Field of the Invention

The present invention relates to input apparatuses.

### 2. Description of the Related Art

A hitherto known personal digital assistant includes a capacitance touch sensor that detects a touch operation on a display surface provided on one main surface of a low-profile casing, a backlight that illuminates the display surface from the back, contact operation keys that detect a user's operation, a hold-state determination means for determining whether the low-profile casing is touched on the side by hand on the basis of the output of the touch sensor, and a display control means for switching the backlight from a light-off state to a light-on state on the basis of the operation on the operation keys and the determination result on the hold state. Another configuration of the personal digital assistant includes a touch sensor for detecting the hold state inside the side of a low-profile casing to detect the hold state (for example, see Japanese Unexamined Patent Application Publication No. 2014-174631 [in particular, FIG. 9]).

In the hitherto known personal digital assistants, touch sensors for detecting a hold state are disposed at the opposite ends of the capacitance touch sensor for detecting a touch operation on the display surface or the opposite ends of the backlight and are therefore difficult to arrange, which complicates the design and may increase the cost, thus posing the problem that they are impractical.

### SUMMARY OF THE INVENTION

The present invention provides an input apparatus with a simple structure and reduced in cost.

An input apparatus according to an embodiment of the present invention includes a casing having an operation surface on an upper surface, an opposite surface opposite to the operation surface, a side surface under a periphery of the operation surface, and an inner space expanding from an opening below the side surface toward the opposite surface, a substrate disposed along the opposite surface in the inner space, a top-surface-operation detecting unit including a first electrode pattern on the upper surface of the substrate, the top-surface-operation detecting unit detecting a change in electrostatic capacitance of the first electrode pattern caused by capacitive coupling to an operating body that comes close to or into contact with the operation surface, a side-surface-operation detecting unit on the side surface of the substrate, below the top-surface-operation detecting unit, the side-surface-operation detecting unit detecting a change in electrostatic capacitance caused according to a side surface operation performed on the side surface of the casing by the operating body, and a control unit that outputs an operation signal based on detection results of the top-surface-operation detecting unit and the side-surface-operation detecting unit.

### BRIEF DESCRIPTION OF THE DRAWINGS

FIG. 1 is a diagram illustrating an input apparatus according to an embodiment;

FIG. 2 is a cross-sectional view taken from arrows II-II in FIG. 1;

FIG. 3 is a block diagram illustrating the circuit configuration of the input apparatus;

FIG. 4A is a diagram illustrating the uppermost wiring layer of the substrate;

FIG. 4B is a diagram illustrating an inner layer (one of a plurality of inner layers) below the uppermost layer shown in FIG. 4A;

FIG. 4C is a diagram illustrating a cross-sectional view taken from arrows IVC-IVC in FIG. 4A;

FIGS. 5A and 5B are diagrams illustrating examples of the output waveforms of top electrode patterns at a top surface operation;

FIGS. 6A and 6B are diagrams illustrating examples of the output waveforms of the top electrode patterns at a top surface operation;

FIG. 7A is a diagram illustrating how a side surface operation on the substrate is performed;

FIGS. 7B1 to 7B8 are diagrams illustrate the temporal changes of the output waveforms of the side electrode patterns;

FIG. 8A is a diagram illustrating a side surface operation for rotating the knob; and

FIG. 8B is a diagram illustrating a top surface operation.

### DESCRIPTION OF THE PREFERRED EMBODIMENTS

Embodiments in which an input apparatus of the present invention is applied will be described hereinbelow.

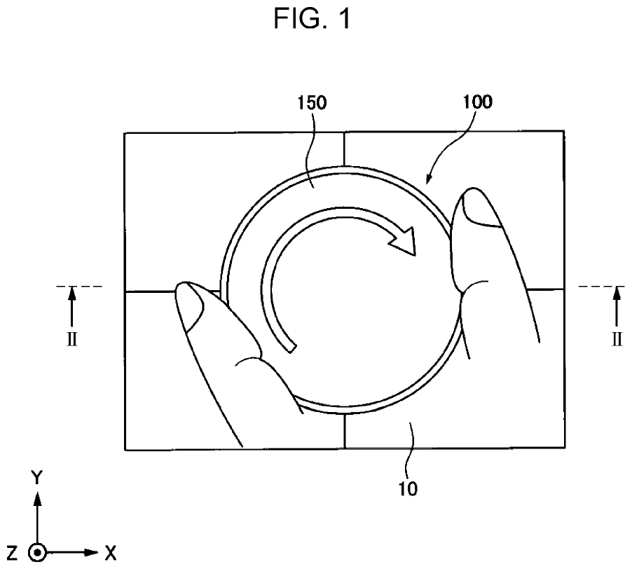

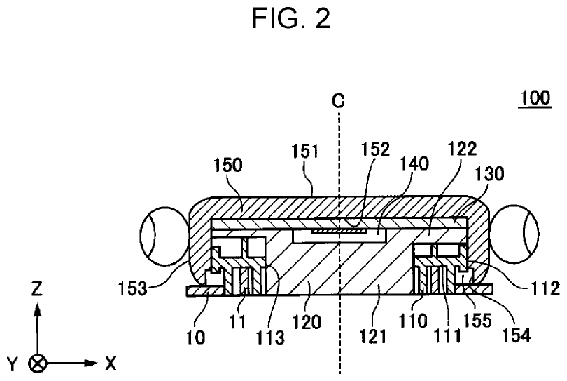

FIG. 1 is a diagram illustrating an input apparatus 100 according to an embodiment. FIG. 2 is a cross-sectional view taken from arrows II-II in FIG. 1. The following will be described using the XYZ coordinate system. Here, it is assumed for convenience of description that the Z-direction corresponds to the vertical direction. However, the Z-direction does not refer to a universal vertical direction.

FIGS. 1 and 2 illustrate user's fingers as an operating body. This illustrates a configuration in which the input apparatus is operated with user's fingers. However, the input apparatus may be operated with anything other than fingers.

Examples of the input apparatus include input apparatuses installed in vehicles and used in remotely operating operation units of graphic user interfaces (GUIs) displayed on operating screens for various apparatuses, such as a navigation apparatus and an air conditioner, displayed on display panels disposed around dashboards. The input apparatus 100 is disposed at close quarters of the driver or the passenger in the passenger seat, such as the center console of a vehicle, for example. However, the utilization form of the input apparatus 100 is not limited to such utilization forms.

The input apparatus 100 includes a base 110, a support 120, a substrate 130, an integrated circuit (IC) chip 140, and a knob 150, as shown in FIG. 2. The IC chip 140 is an example of a control unit, and the knob 150 is an example of a casing.

The base 110 is a member that fixes the input apparatus 100 to a center console 10 of the vehicle and includes a groove 111, a cylindrical portion 112, and a through-hole 113. The base 110 is a ring-shaped member centered on a central axis C.

The groove 111 is recessed from below upward and is fitted and fixed on a protrusion 11 of the center console 10. The cylindrical portion 112 is provided along the outer circumference of the upper portion of the base 110 and slides on the inner circumferential surface of the knob 150 to serve as a rotation shaft. The through-hole 113 passes through the center of the base 110 vertically.

The support 120 includes a cylindrical portion 121 and a disk portion 122. The cylindrical portion 121 is fitted and fixed in the through-hole 113 of the base 110. The disk portion 122 is connected to the upper end of the cylindrical portion 121 and extends radially (radially with respect to the central axis C) from the cylindrical portion 121. The disk portion 122 has a recess at the center of the top so that the IC chip 140 on the substrate 130, to be described later, can be housed.

The substrate 130 is a disk-like wiring board having a plurality of wiring layers and a plurality of insulating layers. The substrate 130 is fixed to the support 120. An example of the substrate 130 is a flame retardant type 4 (FR-4) wiring substrate. The substrate 130 has electrode patterns (not shown in FIG. 2) for detecting an operation on the knob 150.

The IC chip 140 is provided at the center of the lower surface of the substrate 130 and is connected to top electrode patterns 131X and 131Y and side electrode patterns 132X and 132Y, described later, included in the substrate 130 and is connected to a control unit (an electronic control unit [ECU]) of a navigation system, an air conditioner, or the like of the vehicle via harness wires (not shown). The top electrode patterns 131X and 131Y are provided to detect a change in electrostatic capacitance caused by a top surface operation, described later. The side electrode patterns 132X and 132Y are provided to detect a change in electrostatic capacitance caused by a side surface operation, described later.

The IC chip 140 detects a contact or a proximate operation on an operation surface 151 of the knob 150, a contact or a proximate operation and a rotating operation on an outer peripheral surface 153 of the knob 150 on the basis of a change in electrostatic capacitance, detected by the electrode patterns, caused by the capacitive coupling of the user's finger and the electrode patterns. The IC chip 140 outputs an operation signal indicating the details of the operation to the control unit, such as an ECU, of the vehicle.

The knob 150 has the operation surface 151, an opposite surface 152, the outer peripheral surface 153, an opening 154, and an inner space 155. The knob 150 is rotatable about the central axis C, with the cylindrical portion 112 of the base 110 as the axis of rotation. Since the knob 150 is fixed to the support 120 in a state spaced apart from the substrate 130, the substrate 130 is not rotated even if the knob 150 rotates.

The operation surface 151 is the upper surface of the knob 150. The opposite surface 152 is opposite to the operation surface 151. The outer peripheral surface 153 is an example of a side surface at the lower part of the periphery of the operation surface 151. The opening 154 is enclosed by the lower end of the outer peripheral surface 153 and communicates with the inner space 155. The inner space 155 expands from the opening 154 toward the opposite surface 152 and houses the base 110, the support 120, the substrate 130, and the IC chip 140.

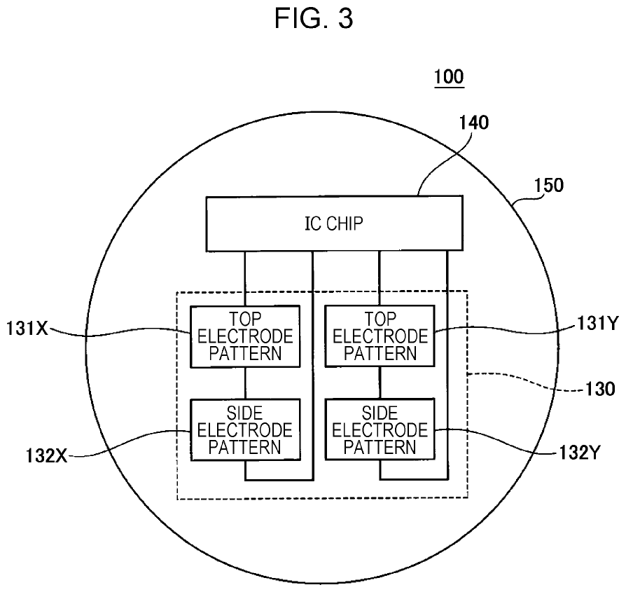

FIG. 3 is a block diagram illustrating the circuit configuration of the input apparatus 100. The IC chip 140 connects to the opposite ends of the series circuit of the top electrode pattern 131X and the side electrode pattern 132X and the opposite ends of the series circuit of the top electrode pattern 131Y and the side electrode pattern 132Y.

In other words, the top electrode pattern 131X and the side electrode pattern 132X and the top electrode pattern 131Y and the side electrode pattern 132Y in the substrate 130 are connected in parallel to the IC chip 140.

Actually, a plurality of (for example, five) series circuits of the top electrode pattern 131X and the side electrode pattern 132X and a plurality of (for example, five) series circuits of the top electrode pattern 131Y and the side electrode pattern 132Y are disposed. Accordingly, ten series circuits of the top electrode pattern and the side electrode pattern are connected in parallel to the IC chip 140.

The IC chip 140 can detect which of a top surface operation and a side surface operation is performed in which of the series circuits on the basis of an electrostatic capacitance detected by the ten series circuits of the top electrode pattern 131X and the side electrode pattern 132X and the top electrode pattern 131Y and the side electrode pattern 132Y (the details of which will be described later).

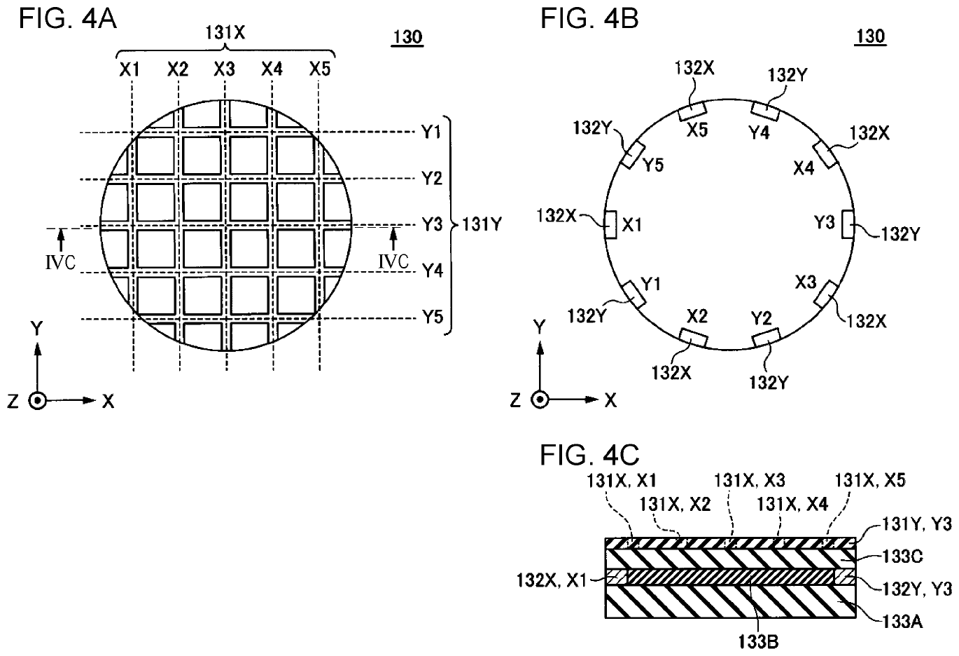

FIGS. 4A to 4C are diagrams illustrating the substrate 130. FIG. 4A illustrates the uppermost wiring layer of the substrate 130. FIG. 4B illustrates an inner layer (one of a plurality of inner layers) below the uppermost layer shown in FIG. 4A. FIG. 4C illustrates a cross-sectional view taken from arrows IVC-IVC in FIG. 4A.

The substrate 130 includes the top electrode patterns 131X (X1 to X5) and 131Y (Y1 to Y5), the side electrode patterns 132X (X1 to X5) and 132Y (Y1 to Y5), and insulating layers 133A, 133B, and 133C.

The substrate 130 has a structure in which the insulating layer 133A, the side electrode patterns 132X (X1 to X5) and 132Y (Y1 to Y5) and the insulating layer 133B, the insulating layer 133C, and the top electrode patterns 131X (X1 to X5) and 131Y (Y1 to Y5) are laminated from bottom to top. FIG. 4C illustrates a cross-sectional view taken from arrows IVC-IVC in FIG. 4A, thus illustrating the side electrode patterns 132X (X1) and 132Y (Y3) of the side electrode patterns 132X (X1 to X5) and 132Y (Y1 to Y5) and the top electrode patterns 131X (X1 to X5) and 131Y (Y3) of the top electrode patterns 131X (X1 to X5) and 131Y (Y1 to Y5).

The upper most layer includes the top electrode patterns 131X (X1 to X5) and 131Y (Y1 to Y5), as shown in FIGS. 4A and 4C. The top electrode patterns 131X (X1 to X5) and 131Y (Y1 to Y5) are examples of a first electrode pattern. The top electrode patterns 131X (X1 to X5) and 131Y (Y1 to Y5), which are examples of the first electrode pattern, are also examples of a top-surface-operation detecting unit.

The top electrode patterns 131X (X1 to X5) and 131Y (Y1 to Y5) are provided to detect an operation (a top surface operation) on the operation surface 151 of the knob 150. In an example, the top electrode patterns 131X (X1 to X5) and 131Y (Y1 to Y5) are made of copper foil.

The top electrode patterns 131X (X1 to X5) are five stripe electrode patterns extending linearly in the Y-axis direction from the end of the substrate 130 in the −Y direction to the end in the +Y direction at intervals in the X-axis direction.

The top electrode patterns 131Y (Y1 to Y5) are five stripe electrode patterns extending linearly in the X-axis direction from the end of the substrate 130 in the −X direction to the end in the +X direction at intervals in the Y-axis direction.

The top electrode patterns 131X (X1 to X5) are arrayed at regular intervals in the X-axis direction. The top electrode patterns 131Y (Y1 to Y5) are arrayed at regular intervals in the Y-axis direction.

The top electrode patterns 131X (X1 to X5) and 131Y (Y1 to Y5) are insulated from one another and are connected to the IC chip 140 with wiring lines (not shown). The top electrode patterns 131X (X1 to X5) and 131Y (Y1 to Y5) are disposed in the uppermost layer of the substrate 130. The substrate 130 is disposed directly below the opposite surface 152 of the knob 150 with a minimum gap therebetween.

This allows the top electrode patterns 131X (X1 to X5) and 131Y (Y1 to Y5) to capacitively couple to a finger coming close to or into contact with the operation surface 151 of the knob 150, thereby detecting a change in electrostatic capacitance according to the position and the direction and amount of movement of the finger that comes close to or into contact with the operation surface 151 in the X-Y plane.

An inner layer of the substrate 130 below the top electrode patterns 131X (X1 to X5) and 131Y (Y1 to Y5) has the side electrode patterns 132X (X1 to X5) and 132Y (Y1 to Y5), as shown in FIGS. 4B and 4C.

The side electrode patterns 132X (X1 to X5) and 132Y (Y1 to Y5) are examples of a second electrode pattern. The side electrode patterns 132X (X1 to X5) and 132Y (Y1 to Y5), which are examples of a second electrode pattern, are also examples of a side-surface-operation detecting unit. In an example, the side electrode patterns 132X (X1 to X5) and 132Y (Y1 to Y5) are made of copper foil.

The side electrode patterns 132X (X1 to X5) and 132Y (Y1 to Y5) are provided to detect an operation (a side surface operation) on the outer peripheral surface 153 of the knob 150.

The side electrode patterns 132X (X1 to X5) are arranged along the outer peripheral end of the substrate 130 and has, in an example, a rectangular shape in plan view. The side electrode patterns 132X (X1 to X5) are arranged along the outer periphery of the substrate 130 at regular intervals (intervals of 72 degrees). The side electrode patterns 132X (X1 to X5) may be provided to the outer peripheral surface of the substrate 130.

The side electrode patterns 132Y (Y1 to Y5) are disposed along the outer peripheral end of the substrate 130 and has, in an example, a rectangular shape in plan view. The side electrode patterns 132Y (Y1 to Y5) are arranged along the outer periphery of the substrate 130 at regular intervals (intervals of 72 degrees).

The side electrode patterns 132X (X1 to X5) and the side electrode patterns 132Y (Y1 to Y5) are arranged alternately at regular intervals along the outer peripheral end of the substrate 130. In other words, ten conductors, the side electrode patterns 132X (X1 to X5) and 132Y (Y1 to Y5), are arranged along the outer peripheral end of the substrate 130 in the same plane.

The ten conductors are preferably spaced apart to some extent to detect a side surface operation. For this reason, the length of each of the side electrode patterns 132X (X1 to X5) and 132Y (Y1 to Y5) in the outer peripheral direction is preferably, in an example, less than or equal to half the length of the outer circumference of the substrate 130 divided into ten.

Since the side electrode patterns 132X (X1 to X5) and 132Y (Y1 to Y5) are provided to detect a side surface operation, the substrate 130 does not need to have a large width in the radial direction, and the conductors should be longer in the circumferential direction than in the radial direction.

The side electrode patterns 132X (X1 to X5) and 132Y (Y1 to Y5) are connected to the top electrode patterns 131X (X1 to X5) and 131Y (Y1 to Y5) shown in FIG. 4A, respectively, into one with vias, wiring lines, and so on (not shown) connecting the layers of the substrate 130.

In other words, each top electrode pattern 131X (X1) and each side electrode pattern 132X (X1) constitute one conductor in the substrate 130. The opposite ends of the top electrode pattern 131X (X1) and the side electrode pattern 132X (X1) are connected to the IC chip 140 via a wiring line (not shown). This also applies to the top electrode patterns 131X (X2 to X5) and 131Y (Y2 to Y5) and the side electrode patterns 132X (X2 to X5) and 132Y (Y2 to Y5).

The side electrode patterns 132X (X1 to X5) and 132Y (Y1 to Y5) are disposed below the top electrode patterns 131X (X1 to X5) and 131Y (Y1 to Y5) and on the back of the top electrode patterns 131X (X1 to X5) and 131Y (Y1 to Y5), seen from the operation surface 151. This makes it difficult to capacitively couple to a finger that comes close to or into contact with the operation surface 151 as compared with the top electrode patterns 131X (X1 to X5) and 131Y (Y1 to Y5).

The side electrode patterns 132X (X1 to X5) and 132Y (Y1 to Y5) are close to the outer peripheral surface 153 of the knob 150 and has no conductor between them and the outer peripheral surface 153, thereby causing capacitive coupling with the finger that comes close to or into contact with the outer peripheral surface 153 of the knob 150.

This allows the side electrode patterns 132X (X1 to X5) and 132Y (Y1 to Y5) to detect a change in electrostatic capacitance according to the position and the direction and amount of movement in the rotating direction of the finger that comes close to or into contact with the outer peripheral surface 153 of the knob 150. The side electrode patterns 132X (X1 to X5) and 132Y (Y1 to Y5) may have positional relationship in which another wiring layer is disposed between them and the uppermost layer in which the top electrode patterns 131X (X1 to X5) and 131Y (Y1 to Y5) are disposed. This is because the configuration can reduce the influence that the top electrode patterns 131X (X1 to X5) and 131Y (Y1 to Y5) exert on the side electrode patterns 132X (X1 to X5) and 132Y (Y1 to Y5).

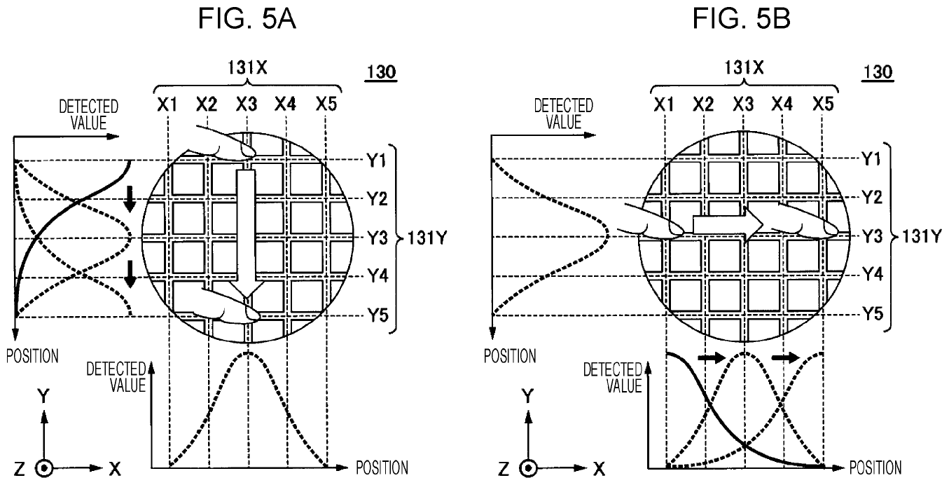

FIGS. 5A and 5B illustrate examples of the output waveforms of the top electrode patterns 131X (X1 to X5) and 131Y (Y1 to Y5) at a top surface operation. FIGS. 5A and 5B show temporal changes of the waveforms of the outputs (detected values) of the top electrode patterns 131X (X1 to X5) below the substrate 130 and temporal changes of the outputs (detected values) of the top electrode patterns 131Y (Y1 to Y5) on the left of the substrate 130. The waveform charts show the relationship between the amplitude (detected value) and the position. The detected value indicates the count value obtained by converting the voltage value to a digital value.

As shown in FIG. 5A, when the finger in contact with the operation surface 151 is moved from the +Y direction side to the −Y direction side along the top electrode pattern 131X (X3), the outputs of the top electrode patterns 131X (X1 to X5) exhibit a sinusoidal pulse that peaks at the position (X3) of the finger and are kept constant without change even if the finger moves, as shown below the substrate 130. At that time, the sinusoidal pulse of the outputs of the top electrode patterns 131Y (Y1 to Y5) that peaks at the position of the finger moves from the +Y direction side to the −Y direction side, as shown on the left of the substrate 130.

As shown in FIG. 5B, when the finger in contact with the operation surface 151 is moved from the −X direction side to the +X direction side along the top electrode pattern 131Y (Y3), the outputs of the top electrode patterns 131Y (Y1 to Y5) form a sinusoidal pulse that peaks at the position (Y3) of the finger and are kept constant without change even if the finger moves, as shown on the left of the substrate 130. At that time, the sinusoidal pulse of the outputs of the top electrode patterns 131X (X1 to X5) that peaks at the position of the finger moves from the −X direction side to the +X direction side, as shown below the substrate 130.

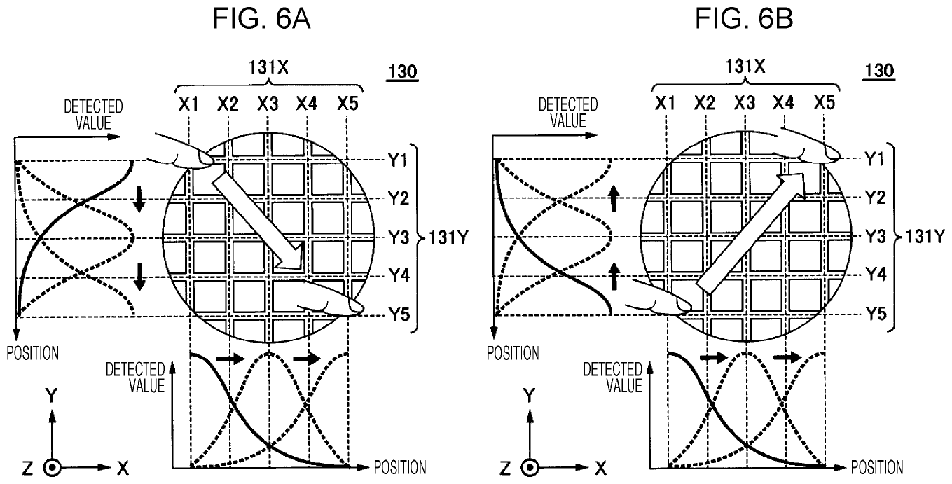

FIGS. 6A and 6B illustrate examples of the output waveforms of the top electrode patterns 131X (X1 to X5) and 131Y (Y1 to Y5) at a top surface operation. FIGS. 6A and 6B illustrate the output waveforms of the top electrode patterns 131X (X1 to X5) and 131Y (Y1 to Y5) when the finger in contact with the operation surface 151 is moved at an angle of 45 degrees with respect to the X-axis and the Y-axis. How the waveforms are shown is the same as in FIGS. 5A and 5B.

As shown in FIG. 6A, when the finger in contact with the operation surface 151 is moved obliquely from the −X direction side and the +Y direction side to the +X direction side and the −Y direction side with respect to the substrate 130, the outputs of the top electrode patterns 131X (X1 to X5) and 131Y (Y1 to Y5) form a sinusoidal pulse having a peak at the position of the finger and moving in the moving direction of the finger.

As shown in FIG. 6B, when the finger in contact with the operation surface 151 is moved from the −X direction side and the −Y direction side to the +X direction side and the +Y direction side with respect to the substrate 130, the outputs of the top electrode patterns 131X (X1 to X5) and 131Y (Y1 to Y5) form a sinusoidal pulse having a peak at the position of the finger and moving in the moving direction of the finger.

As shown in FIGS. 5A and 5B and FIGS. 6A and 6B, when the finger in contact with the operation surface 151 is moved, the outputs of the top electrode patterns 131X (X1 to X5) and 131Y (Y1 to Y5) form a sinusoidal pulse that changes continuously with the movement of the finger in the X direction and the Y direction.

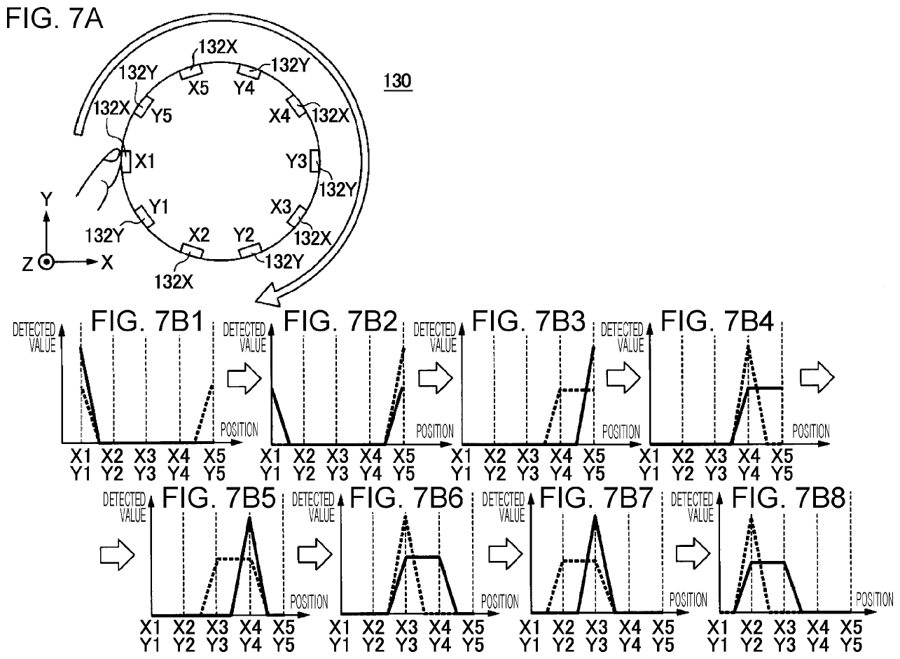

FIGS. 7B1 to 7B8 illustrate examples of the output waveforms of the side electrode patterns 132X (X1 to X5) and 132Y (Y1 to Y5) at a side surface operation. FIG. 7A illustrates how a side surface operation on the substrate 130 is performed. FIGS. 7B1 to 7B8 illustrate the temporal changes of the output waveforms of the side electrode patterns 132X (X1 to X5) and 132Y (Y1 to Y5).

The output waveform of the side electrode patterns 132X (X1 to X5) is indicated by the solid line, and the output waveform of the side electrode patterns 132Y (Y1 to Y5) is indicated by the broken line. The waveform charts show the relationship between the amplitude (detected value) of the waveform and the position, as in FIGS. 5A and 5B and FIGS. 6A and 6B.

In an example, the knob 150 is rotated by a side surface operation, and the position of the finger moves clockwise from the side electrode pattern 132X (X1) to the side electrode pattern 132Y (Y2). The waveform at that time shows a situation in which the position of the finger shifts one by one to the adjacent electrode pattern from FIGS. 7B1 to 7B8 as indicated by the arrows.

First, as shown in FIG. 7B1, the output (detected value) of the side electrode pattern 132X (X1) becomes maximum, and the outputs of (detected values) of the side electrode patterns 132X (X2 to X5) are almost zero. The outputs (detected values) of the side electrode patterns 132Y (Y1) and 132Y (Y5) next to the side electrode pattern 132X (X1) are half the output (detected value) of the side electrode pattern 132X (X1).

Next, as shown in FIG. 7B2, the output (detected value) of the side electrode pattern 132Y (Y5) becomes maximum, and the outputs (detected values) of the side electrode patterns 132Y (Y1 to Y4) are almost zero. The outputs (detected values) of the side electrode patterns 132X (X1) and 132X (X5) next to the side electrode pattern 132Y (Y5) are half the output (detected value) of the side electrode pattern 132Y (Y5).

Next, as shown in FIG. 7B3, the output (detected value) of the side electrode pattern 132X (X5) becomes maximum, and the outputs (detected values) of the side electrode patterns 132X (X1 to X4) are almost zero. The outputs (detected values) of the side electrode patterns 132Y (Y5) and 132Y (Y4) next to the side electrode pattern 132X (X5) are half the output (detected value) of the side electrode pattern 132X (X5).

Next, as shown in FIG. 7B4, the output (detected value) of the side electrode pattern 132Y (Y4) becomes maximum, and the outputs (detected values) of the side electrode patterns 132Y (Y1 to Y3, and Y5) are almost zero. The outputs (detected values) of the side electrode patterns 132X (X5) and 132X (X4) next to the side electrode pattern 132Y (Y4) are half the output (detected value) of the side electrode pattern 132Y (Y4).

Next, as shown in FIG. 7B5, the output (detected value) of the side electrode pattern 132X (X4) becomes maximum, and the outputs (detected values) of the side electrode patterns 132X (X1 to X3, and X5) are almost zero. The outputs (detected values) of the side electrode patterns 132Y (Y4) and 132Y (Y3) next to the side electrode pattern 132X (X4) are half the output (detected value) of the side electrode pattern 132X (X4).

Next, as shown in FIG. 7B6, the output (detected value) of the side electrode pattern 132Y (Y3) becomes maximum, and the outputs (detected values) of the side electrode patterns 132Y (Y1 to Y2 and Y4 to Y5) are almost zero. The outputs (detected values) of the side electrode patterns 132X (X4) and 132X (X3) next to the side electrode pattern 132Y (Y3) are half the output (detected value) of the side electrode pattern 132Y (Y3).

Next, as shown in FIG. 7B7, the output (detected value) of the side electrode pattern 132X (X3) becomes maximum, and the outputs (detected values) of the side electrode patterns 132X (X1 to X2 and X4 to X5) are almost zero. The outputs (detected values) of the side electrode patterns 132Y (Y3) and 132Y (Y2) next to the side electrode pattern 132X (X3) are half the output (detected value) of the side electrode pattern 132X (X3).

Lastly, as shown in FIG. 7B8, the output (detected value) of the side electrode pattern 132Y (Y2) becomes maximum, and the outputs (detected values) of the side electrode patterns 132Y (Y1 and Y3 to Y5) are almost zero. The outputs (detected values) of the side electrode patterns 132X (X3) and 132X (X2) next to the side electrode pattern 132Y (Y2) are half the output (detected value) of the side electrode pattern 132Y (Y2).

Thus, in the case of the side surface operation, the side electrode patterns 132X (X1 to X5) and 132Y (Y1 to Y5) are disconnected in the outer peripheral direction of the substrate 130. This does not form a continuous sinusoidal output waveform, as shown in FIGS. 5A and 5B and FIGS. 6A and 6B and differs from the output waveform at the top surface operation.

More specifically, the change in electrostatic capacitance of the top electrode patterns 131X (X1 to X5) and 131Y (Y1 to Y5) generated at a continuous finger operation on the operation surface 151 and the change in electrostatic capacitance of the side electrode patterns 132X (X1 to X5) and 132Y (Y1 to Y5) generated at a continuous finger operation on the outer peripheral surface 153 form different transition patterns. In other words, the side surface operation can form an output waveform apparently different from that in the continuous top surface operation.

For that reason, by storing data indicating the output waveforms shown in FIGS. 5A and 5B to FIGS. 7B1 to 7B8 in an internal memory of the IC chip 140, when receiving an output waveform indicating the detection result of the top electrode patterns 131X (X1 to X5) and 131Y (Y1 to Y5) or the side electrode patterns 132X (X1 to X5) and 132Y (Y1 to Y5) at a top surface operation or a side surface operation, the IC chip 140 can determine which of the top surface operation and the side surface operation has been performed, according to the pattern of the output waveform.

Furthermore, the position and the direction and amount of movement of the finger due to the top surface operation or the side surface operation can be detected on the basis of the output waveform indicating the detection result of the top electrode patterns 131X (X1 to X5) and 131Y (Y1 to Y5) or side electrode patterns 132X (X1 to X5) and 132Y (Y1 to Y5).

The discrimination between the top surface operation and the side surface operation can be performed on the basis of the output waveform indicating the detection result of the top electrode patterns 131X (X1 to X5) and 131Y (Y1 to Y5) or the side electrode patterns 132X (X1 to X5) and 132Y (Y1 to Y5) disposed in the substrate 130.

The substrate 130 has the top electrode patterns 131X (X1 to X5) and 131Y (Y1 to Y5) in the uppermost layer and has the side electrode patterns 132X (X1 to X5) and 132Y (Y1 to Y5) in an inner layer. This structure is simple, allowing low-cost production.

This allows providing the input apparatus 100 with a simple structure and reduced cost.

The embodiment can provide the input apparatus 100 that allows discrimination between a top surface operation and a side surface operation, as described above. The input apparatus allows the position (coordinates) and the direction and amount of movement of the finger to be detected in any top surface operation on the upper surface of the knob 150. Although the embodiment shows an example in which one finger is used, the detection is also possible in the case of two or more fingers. This allows determination of a rotating operation with the knob 150 put between fingers.

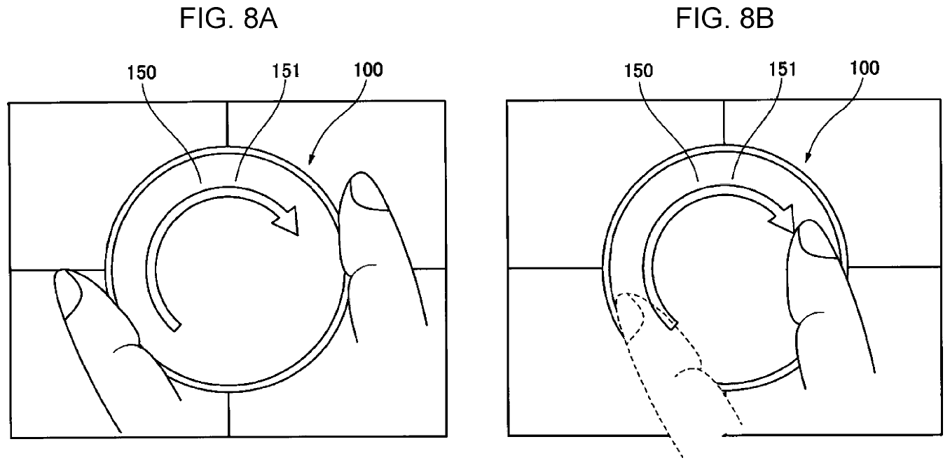

FIGS. 8A and 8B are diagrams illustrating the effects of the input apparatus 100. FIG. 8A is a diagram illustrating a side surface operation for rotating the knob 150. FIG. 8B is a diagram illustrating a top surface operation.

In the top surface operation shown in FIG. 8B, one finger is in contact with the vicinity of the outer peripheral end of the operation surface 151 of the knob 150, and the finger keeps contact with the operation surface 151 from the position of the finger indicated by the broken line to the position of the finger indicated by the solid line to perform an input in an arch shape.

Such a top surface operation causes the top electrode patterns 131X (X1 to X5) and 131Y (Y1 to Y5) to output sinusoidal continuous waveforms, as shown in FIGS. 5A and 5B and FIGS. 6A and 6B. At that time, even if the side electrode patterns 132X (X1 to X5) and 132Y (Y1 to Y5) make outputs, and the outputs are superimposed on the output waveforms of the top electrode patterns 131X (X1 to X5) and 131Y (Y1 to Y5), there is no problem in discriminating between the top surface operation and the side surface operation if the output waveforms are weaker than the output waveforms of the top electrode patterns 131X (X1 to X5) and 131Y (Y1 to Y5).

If a side surface operation is performed, as shown in FIG. 8A, the output waveforms, as shown in FIGS. 7, are input from the side electrode patterns 132X (X1 to X5) and 132Y (Y1 to Y5) to the IC chip 140. The output waveforms shown in FIGS. 7B1 to 7B8 are completely different from the output waveforms shown in FIGS. 5A and 5B and FIGS. 6A and 6B. In the case of the side surface operation, the finger comes into contact with the outer peripheral surface 153 below the operation surface 151 of the knob 150. For this reason, the outputs of the top electrode patterns 131X (X1 to X5) and 131Y (Y1 to Y5), if produced, are weaker than the outputs of the side electrode pattern 132X (X1 to X5) and 132Y (Y1 to Y5).

Therefore, even if one finger moves in an arc shape while keeping contact with the vicinity of the outer peripheral end of the operation surface 151 of the knob 150, as shown in FIG. 8B, the operation can be discriminated from the side surface operation shown in FIG. 8A. This applies also to a case in which a top surface operation is performed with two fingers and a case in which a side surface operation for rotating the knob 150 is performed with one finger.

For a top surface operation in which a finger only touches the vicinity of the outer peripheral end of the operation surface 151 without moving in an arc shape, changes in the electrostatic capacitance values of the top electrode patterns 131X (X1 to X5) and 131Y (Y1 to Y5) are mainly detected, and for a side surface operation in which a finger only touches the outer peripheral surface 153 of the knob 150, changes in the electrostatic capacitance values of the side electrode patterns 132X (X1 to X5) and 132Y (Y1 to Y5) are mainly detected. This also allows discrimination between these operations by comparing the output values of the top electrode patterns 131X (X1 to X5) and 131Y (Y1 to Y5) and the side electrode patterns 132X (X1 to X5) and 132Y (Y1 to Y5).

Thus, the embodiment can provide the input apparatus 100 in which a top surface operation and a side surface operation can be discriminated from each other.

Furthermore, the top electrode patterns 131X (X1 to X5) and 131Y (Y1 to Y5) and the side electrode patterns 132X (X1 to X5) and 132Y (Y1 to Y5) can be mounted in a single substrate 130. This allows a configuration without substantial addition of components, thereby providing the input apparatus 100 in which a top surface operation and a side surface operation can be discriminated with a simple configuration.

Furthermore, the side electrode patterns 132X (X1 to X5) and 132Y (Y1 to Y5) are disposed below the top electrode patterns 131X (X1 to X5) and 131Y (Y1 to Y5). This allows space-saving as compared with a configuration in which the electrode patterns are disposed in an X-Y plane of the substrate 130. The side electrode patterns 132X (X1 to X5) and 132Y (Y1 to Y5) may be disposed in the lowermost layer of the substrate 130 (under the insulating layer 133A shown in FIG. 4C). This also allows space-saving.

The top electrode patterns 131X (X1 to X5) and the side electrode patterns 132X (X1 to X5) are each implemented by a single conductor in the substrate 130. The top electrode patterns 131Y (Y1 to Y5) and the side electrode patterns 132Y (Y1 to Y5) are each implemented by a single conductor in the substrate 130. The opposite ends of each of the conductors of the top electrode patterns 131X (X1 to X5) and the side electrode patterns 132X (X1 to X5) are connected to the IC chip 140. The opposite ends of each of the conductors of the top electrode patterns 131Y (Y1 to Y5) and the side electrode patterns 132Y (Y1 to Y5) are connected to the IC chip 140.

This allows, even if two electrode patterns (the top electrode patterns 131X (X1 to X5) and 131Y (Y1 to Y5) and the side electrode patterns 132X (X1 to X5) and 132Y (Y1 to Y5)) are used, discrimination between a top surface operation and a side surface operation as well as detection using a single control unit. In other words, there is no need to provide two control units for discriminating between a top surface operation and a side surface operation and detecting the position (coordinates) and the direction and amount of movement of the finger in the IC chip 140, and there is no need to provide two IC chips 140.

In the above description, the two electrode patterns (the top electrode patterns 131X (X1 to X5) and 131Y (Y1 to Y5) and the side electrode patterns 132X (X1 to X5) and 132Y (Y1 to Y5)) have different patterns in plan view. This improves their individual detection accuracy.

In the above description, five top electrode patterns 131X (X1 to X5) and 131Y (Y1 to Y5) for detecting a top surface operation are arranged in each of the X direction and the Y direction. However, the number of top electrode patterns may be set as appropriate and may differ between in the X direction and in the Y direction.

In the above description, ten side electrode patterns 132X (X1 to X5) and 132Y (Y1 to Y5) for detecting a side surface operation are disposed. However, the number of electrodes may be set as appropriate according to the size or the resolution of the knob 150.

In the above description, the knob 150 is rotatable with respect to the base 110. However, the knob 150 does not need to be rotatable and may be fixed. In this case, the knob 150 and the substrate 130 may be disposed in contact with each other without a space. If the knob 150 is fixed, a rotating operation can be performed by sliding a finger on the outer peripheral surface 153 of the knob 150.

Although an input apparatus according to an exemplary embodiment of the present invention has been described above, the present invention is not limited to the specifically disclosed embodiment and may be variously modified or changed without departing from the scope of the claims.

What is claimed is:

1. An input apparatus comprising:
a casing having an operation surface on an upper surface, an opposite surface opposite to the operation surface, a side surface under a periphery of the operation surface, and an inner space expanding from an opening below the side surface toward the opposite surface;
a substrate disposed along the opposite surface in the inner space;
a top-surface-operation detecting unit including a first electrode pattern on the upper surface of the substrate, the top-surface-operation detecting unit detecting a change in electrostatic capacitance of the first electrode pattern caused by capacitive coupling to an operating body that comes close to or into contact with the operation surface;
a side-surface-operation detecting unit on the side surface of the substrate, below the top-surface-operation detecting unit, the side-surface-operation detecting unit detecting a change in electrostatic capacitance caused according to a side surface operation performed on the side surface of the casing by the operating body; and
a control unit that outputs an operation signal based on detection results of the top-surface-operation detecting unit and the side-surface-operation detecting unit.

2. The input apparatus according to claim 1, wherein the side-surface-operation detecting unit is connected to the first electrode pattern constituting the top-surface-operation detecting unit to form a single unit.

3. The input apparatus according to claim 2, wherein the side-surface-operation detecting unit includes a second electrode pattern in an inner layer or a bottom layer of the substrate, the side-surface-operation detecting unit detecting a change in electrostatic capacitance of the second electrode pattern caused by capacitive coupling to the operating body that comes close to or into contact with the side surface.

4. The input apparatus according to claim 3,
wherein the first electrode pattern includes a plurality of electrodes that performs capacitive coupling to the operating body,
wherein the second electrode pattern includes a plurality of electrodes that performs capacitive coupling to the operating body,
wherein a change in electrostatic capacitance of the plurality of electrodes of the first electrode pattern caused at continuous operation of the operating body on the operation surface and a change in electrostatic capacitance of the plurality of electrodes of the second electrode pattern caused at continuous operation of the operating body on the side surface have different transition patterns, and
wherein the control unit discriminates between proximity or contact of the operating body to the operation surface and the side surface operation based on a difference between the transition patterns.

5. The input apparatus according to claim 4,
wherein the casing is rotatable along the periphery of the operation surface, and
wherein the side-surface-operation detecting unit is configured to detect the rotating operation as the side surface operation.

6. The input apparatus according to claim 1, wherein the side-surface-operation detecting unit includes a second electrode pattern in an inner layer or a bottom layer of the substrate, the side-surface-operation detecting unit detecting a change in electrostatic capacitance caused by proximity or contact of the operating body.

7. The input apparatus according to claim 6,
wherein the first electrode pattern includes a plurality of electrodes that performs capacitive coupling to the operating body,
wherein the second electrode pattern includes a plurality of electrodes that performs capacitive coupling to the operating body,
wherein a change in electrostatic capacitance of the plurality of electrodes of the first electrode pattern caused at continuous operation of the operating body on the operation surface and a change in electrostatic capacitance of the plurality of electrodes of the second electrode pattern caused at continuous operation of the operating body on the side surface have different transition patterns, and
wherein the control unit discriminates between proximity or contact of the operating body to the operation surface and the side surface operation based on a difference between the transition patterns.

8. The input apparatus according to claim 7,
wherein the casing is rotatable along the periphery of the operation surface, and
wherein the side-surface-operation detecting unit is configured to detect the rotating operation as the side surface operation.

9. The input apparatus according to claim 1,
wherein the casing is rotatable along the periphery of the operation surface, and
wherein the side-surface-operation detecting unit is configured to detect the rotating operation as the side surface operation.

10. The input apparatus according to claim 2,
wherein the casing is rotatable along the periphery of the operation surface, and
wherein the side-surface-operation detecting unit is configured to detect the rotating operation as the side surface operation.

11. The input apparatus according to claim 3,
wherein the casing is rotatable along the periphery of the operation surface, and
wherein the side-surface-operation detecting unit is configured to detect the rotating operation as the side surface operation.
